(19) United States
(12) Patent Application Publication
(10) Pub. No.: US 2019/0219648 A1
(43) Pub. Date: Jul. 18, 2019

(54) ELASTIC RADIO FREQUENCY COIL

(71) Applicant: The University of North Carolina at Chapel Hill Office of Commercialization and Economic, Chapel Hill, NC (US)

(72) Inventors: Weili Lin, Chapel Hill, NC (US); Shumin Wang, Chapel Hill, NC (US)

(21) Appl. No.: 16/329,606

(22) PCT Filed: Aug. 30, 2017
(86) PCT No.: PCT/US2017/049398

§ 371 Date: Feb. 28, 2019

Related U.S. Application Data
(60) Provisional application No. 62/381,365, filed on Aug. 30, 2016.

(51) Int. Cl. G01R 33/34; G01R 33/3415; G01R 33/36

(52) U.S. Cl. CPC G01R 33/34046; G01R 33/365; G01R 33/3415

(57) ABSTRACT

This specification describes RF coils using an elastic substrate that can be stretched and/or wrapped around the target anatomy. In some examples, a system includes an RF coil array including at least one elastic and conductive loop, the elastic and conductive loop having a length and being elastic in that, in response to a stress, the length stretches from a first length to a second length greater than the first length and returns to the first length after removal of the stress. The elastic and conductive loop is configurable to surround at least a portion of a magnetic resonance imaging subject's body for magnetic resonance imaging of the portion of the subject's body. The system includes an RF circuit coupled to the RF coil array and configured to cause a voltage to be induced through the elastic and conductive loop.

### PRIORITY CLAIM

This application claims the benefit of U.S. Provisional Patent Application Ser. No. 62/381,365 filed Aug. 30, 2016, the disclosure of which is incorporated herein by reference in its entirety.

### TECHNICAL FIELD

This specification relates generally to radio frequency (RF) coils and more particularly to RF coils for magnetic resonance imaging (MRI) systems.

### BACKGROUND

Despite remarkable development of magnetic resonance imaging (MRI) hardware and image acquisition methods in the past decade, improving MR image signal-to-noise ratio (SNR) by developing novel radio-frequency (RF) coils continues to be an actively pursued area of research as a high SNR can be the key to a successful MR study. A high SNR can be used to obtain high resolution images, shorten data acquisition time or both. MRI techniques such as functional MRI, diffusion-weighted imaging, and dynamic contrast enhanced MRI, all rely on the ability to acquire high-SNR signals rapidly. Low-SNR acquisition can lead to inferior spatial resolution, poor tissue contrast, limited detectability of diseases, longer scan time, and various artifacts caused by respiration or other physiological changes during signal acquisition that are detrimental to nearly all imaging applications.

Although high-field MRI systems such as 7 T MR offer improved SNR when compared to field strengths commonly employed in clinical practice, the staggering cost and challenging technical issues have critically limited its practicality and potential usefulness. Alternatively, multi-channel coil arrays can be used to improve SNR. Specifically, the extent to which SNR is improved depends on the distance between the array coils and the object of interest, the shorter the distance, the higher SNR gain.

Therefore, it may be desirable to design a phase-array coil that tightly fits to the object of interest. However, this design can be cost inhibitive since it means that a coil is needed for each object of interest as the size and shape can vary between subjects. Currently, array coils are often mounted inside a rigid enclosure that fits the curvature of the target anatomy, for instance, the head or the knee. Such a housing needs to be large enough in order to accommodate as many subjects as possible. A main issue of this approach is that the SNR drops quickly when imaging a small head or knee due to the large separation between the coil and the object. The current design also poses a major limitation for MSK applications since it is often preferred to have subjects bend their joints in order to achieve optimal diagnostic results. This may not be possible for a joint inside a rigid enclosure.

### SUMMARY

This specification describes RF coils using an elastic substrate that can be stretched and/or wrapped around the target anatomy. In some examples, a system includes an RF coil array including at least one elastic and conductive loop, the elastic and conductive loop having a length and being elastic in that, in response to a stress, the length stretches from a first length to a second length greater than the first length and returns to the first length after removal of the stress. The elastic and conductive loop is configurable to surround at least a portion of a magnetic resonance imaging subject's body for magnetic resonance imaging of the portion of the subject's body. The system includes an RF circuit coupled to the RF coil array and configured to cause a voltage to be induced through the elastic and conductive loop.

The RF coils are able to change their shape and size as a result of stretching. An RF coil array can therefore fit very closely to a range of different shapes and sizes. The SNR gain will be maximized due to the extremely close and consistent distance between coils and the subject. A simple analysis predicts that a 70-mm 3-Tesla coil positions 3-mm away from the subject will double the SNR than that positioned 3-cm away, a similar SNR gain going from 3 T to 7 T but without the associated high costs and technical challenges of a 7 T scanner. In addition, such elastic coils can enable free joint movement and optimized diagnostic benefits.

This specification describes at least four features that enable the use of elastic RF coil arrays: 1) an elastic substrate for RF coils, which can be stretched and wrapped around the target anatomy, 2) RF coils that can change their shape and size, 3) low-variability RF circuits that maintain a stable and high performance when coils change their shape and size, and 4) the ability for an increasing number of RF channels without reducing the size of the array.

The computer systems described in this specification may be implemented in hardware, software, firmware, or combinations of hardware, software and/or firmware. In some examples, the computer systems described in this specification may be implemented using a non-transitory computer readable medium storing computer executable instructions that when executed by one or more processors of a computer cause the computer to perform operations. Computer readable media suitable for implementing the subject matter described in this specification include non-transitory computer-readable media, such as disk memory devices, chip memory devices, programmable logic devices, random access memory (RAM), read only memory (ROM), optical read/write memory, cache memory, magnetic read/write memory, flash memory, and application-specific integrated circuits. In addition, a computer readable medium that implements the subject matter described in this specification may be located on a single device or computing platform or may be distributed across multiple devices or computing platforms.

### BRIEF DESCRIPTION OF THE FIGURES

FIGS. 1A-C illustrate an example elastic form-fitting housing;

FIGS. 2A-H illustrate example elastic coils;

FIGS. 3A-B illustrate example RF circuits for an MRI system using an elastic RF coil;

FIGS. 4A-B compare performances of example pre-amplifiers;

FIG. 5 is an example Smith chart that illustrates some design principles of low-variability pre-amplifiers;

FIGS. 6A-C show 3-Tesla MRI images; and

FIGS. 7A-F illustrate the ability of using a pre-amplifier for mutual decoupling.

### DESCRIPTION

In contrast to existing rigid or flexible coil housings, the MRI systems described in this specification use RF coils mounted on a substrate that can be stretched and wrapped around the target anatomy, e.g., the head or the knee.

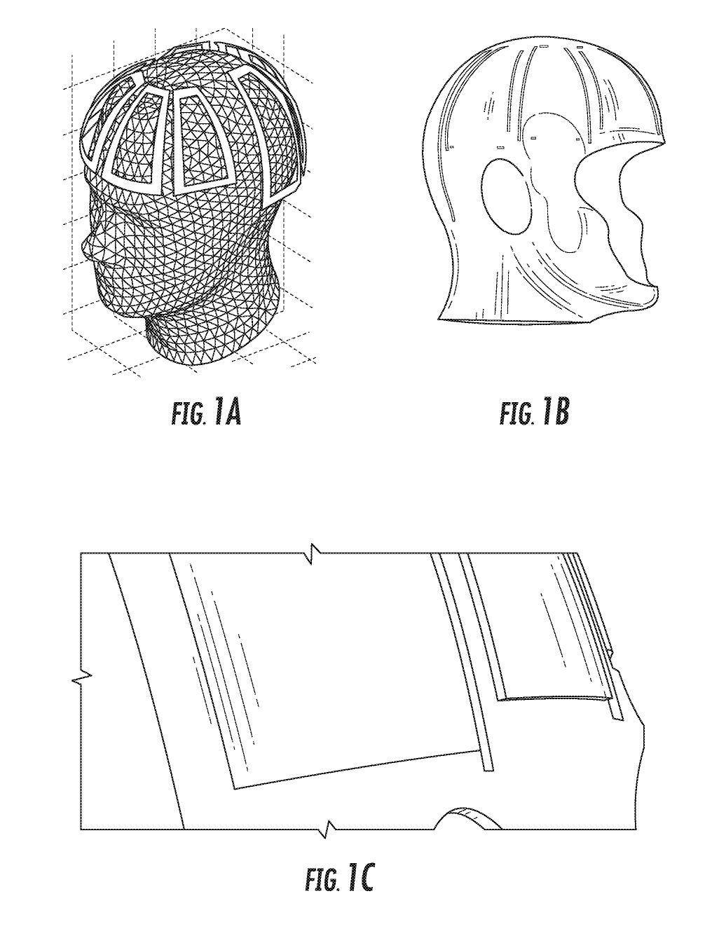

FIGS. 1A-C illustrate an example elastic form-fitting housing, which is designed for an eight-channel brain imaging array. FIG. 1A shows an example eight-channel head coil array. FIG. 1B shows an elastic coil housing design. FIG. 1C shows a closer view of grooves on the housing surface for mounting RF coils.

The dimensions of the housing along the anterior-posterior and the left-right directions can be calculated by subtracting three times of the standard deviations of the head dimension in respective directions from their mean values. For elastic materials with an elongation ratio of 30%, 99.7% of adult human heads can fit in the same housing. The grooves on the housing surface are reserved to accommodate RF coils, but they are optional. The chin area of the housing is open, but can be closed as well. During MRI scan, the opening may be closed by a plastic zipper or a chin strap.

Any elastic material that neither gives rise to MRI signal nor disturbs the static magnetic field can be used to fabricate the housing. Some examples include neoprene, cast urethane, and spandex. Different materials may require different coil fabrication techniques. For instance, urethane housing with a low Shore rating can be molded. Neoprene or spandex housing may need to be sewed.

Depending on the material and fabrication techniques, the elongation rate can be different. For instance, low-Shore urethane housing is less durable but stretchable by two to three times. Neoprene housing is more resistant to tearing but stretchable by only 20-30%. The exact type of material or a combination of different materials can be chosen according to the practical requirements. For instance, neoprene may be appropriate for musculoskeletal imaging because the housing is expected to be pulled up and down often. The housing can be designed as an enclosed structure, or an open structure that can be closed to form an enclosed structure. In general, the system can use any appropriate material, manufacturing technique, or form-fitting design.

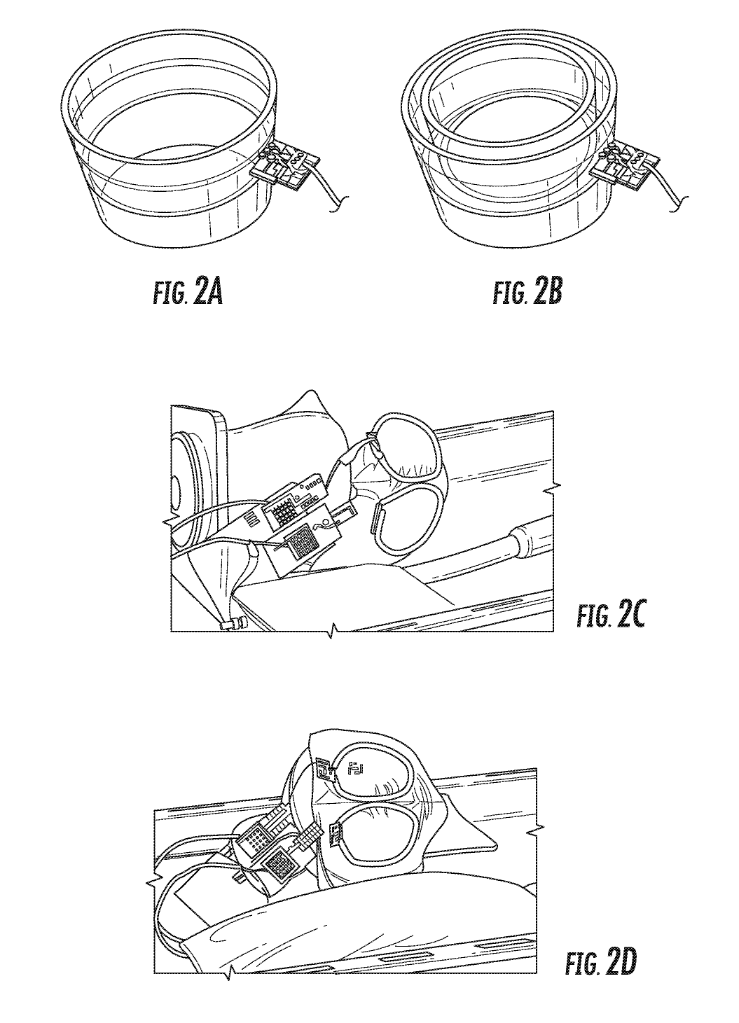

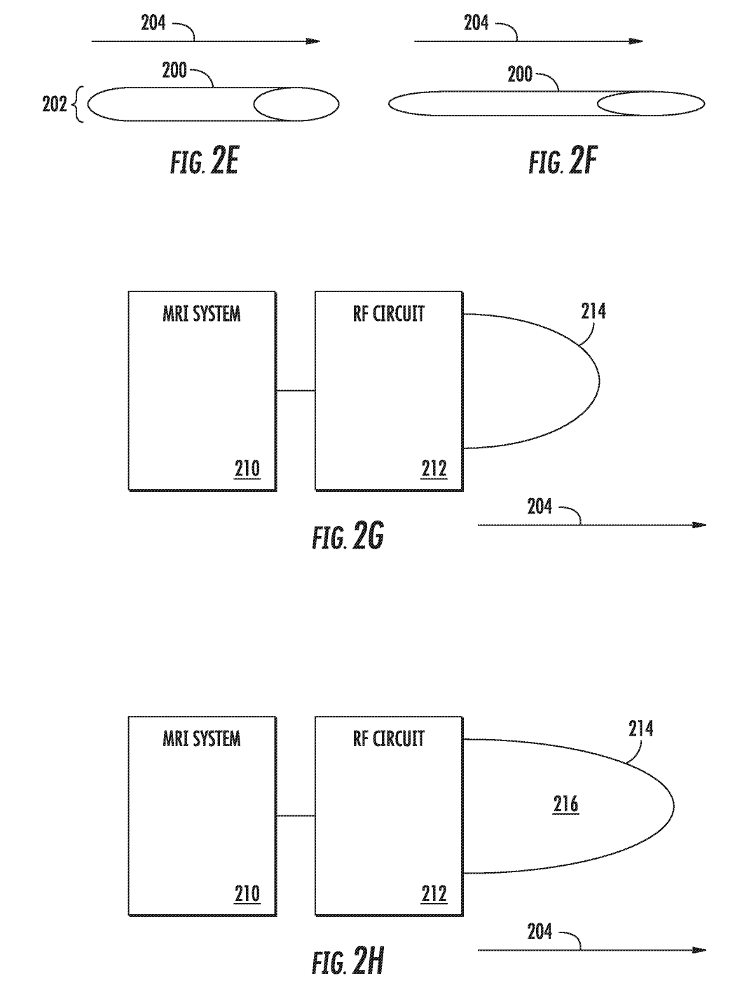

The MRI systems described in the system can be configured to use one or more elastic RF coils. FIGS. 2A-H illustrate example elastic coils implemented by two different ways. FIG. 2A shows an example elastic liquid-metal coil stretched on an 8 cm plastic cylinder and FIG. 2B shows the coil stretched on a 10 cm plastic cylinder. FIG. 2C shows two elastic coils made by elastic wires positioned on a head-shaped phantom and FIG. 2D shows the coils positioned on a spherical phantom on a 3-Tesla MRI scanner. A low variability RF circuit is soldered onto the coils.

The first example, shown in FIGS. 2A-B, uses Indium Gallium alloy, a type of liquid metal packaged inside an elastomeric tube. It can be stretched by a very large extent. The second example, shown in FIGS. 2C-D, uses thin and soft stranded copper wires coiled inside a latex tube. When the tube is stretched to its maximum extent, the wire length corresponds to the circumference of the largest coil expected for a particular MRI system. When the tube is fully relaxed, the wire coils back into a toroid and the length of the latex tube corresponds to the circumference of the smallest coil expected for the MRI system.

The shape, surface area, and overall conductor length of a RF coil can be selected as appropriate for different applications. The RF coils are elastic in that the coverage area and conductor length can vary from subject to subject to fit the specific anatomy of a particular subject. Such elastic coils can be implemented in a number of different ways.

For instance, one can use highly elastic liquid metal packaged inside an elastomeric tube to construct the entire coil, as long as the SNR is satisfactory. One can also connect solid or stranded copper wires by using short segments of loose wires or other appropriate conducting materials that can move to accommodate a target. This option may be mechanically more constrained but offers high electric conductivity.

A finished coil can be terminated in any appropriate manner. For instance, one can solder an RF coil directly on a circuit board for tuning, impedance matching, and signal amplification. This approach has better system integrity but the soldering process may cause heat-induced material breakdown. Instead, one can also terminate each coil by a pair of non-magnetic male jumper pins or connectors of the same sort. The rest of the RF circuit can be plugged in via a pair of female jumper connectors. The contact can be either directly on the coil, or some distance away by using a specific length of transmission line. This solderless approach can avoid heat-induced damage to the elastic housing, but have challenging cable management for large-scale array. In an extreme case, mechanical contact can be completely avoided by using critical inductive coupling. This approach does not cause mechanical concerns, but may be only applicable to a few well-decoupled coils.

The choice of conductor material, coil fabrication technique, and packaging method can be determined by considering the SNR requirement, the desired coil elongation rate, cost, toxicity, durability, and other engineering issues. In general, the RF coils can comprise any appropriate conducting material, coil fabrication technique, and packaging method.

FIGS. 2E and 2F illustrate an elastic wire 200 that can be used to form an elastic RF coil. The elastic wire 200 has a thickness 202 (e.g., a diameter when the elastic wire 200 is cylindrical) and a length in a lateral direction 204. FIG. 2E shows the elastic wire 200 in an unstressed state. FIG. 2F shows the elastic wire 200 under stress so that the length of the elastic wire 200 stretches from a first length (shown in FIG. 2E) to a second length (shown in FIG. 2F) greater than the first length.

The thickness 202 of the elastic wire may decrease as a result of the stress, depending on the implementation of the elastic wire 200. When the stress is released on the elastic wire 200, the length of the elastic wire 200 returns to the first length (shown in FIG. 2E). The thickness 202, if decreased in the stressed state, will also return to its original state.

FIGS. 2G and 2H illustrate an example MRI system 210. The MRI system 210 is coupled to an RF circuit 212, and the RF circuit 212 is coupled to at least one elastic and conductive loop 214. In some examples, the MRI system 210 will use multiple elastic and conductive loops to cover a target. The MRI system 210 can include MRI circuits and a computer system including one or more processors, a display, a user input device, and code for causing the processors execute MRI test routines and produce MRI images.

The elastic and conductive loop 214 can be formed, e.g., of the elastic wire 200 of FIGS. 2E and 2F. FIG. 2G shows the elastic and conductive loop 214 in an unstressed state. FIG. 2H shows the conductive loop 214 in a stressed state so that the length of the elastic and conductive loop has been stretched, e.g., as described above with reference to FIGS. 2E and 2F but along the loop instead of in a straight line.

In operation, a system operator stretches the elastic and conductive loop 214 to wrap an anatomical part of a patient, e.g., by fitting an elastic substrate housing the elastic and conductive loop 214 to a head, knee, or shoulder. The MRI system 210 causes temporal changes of magnetic flux which induces a current in the RF circuit 212 through the elastic and conductive loop 214. The MRI system 210 produces at least one MRI image using a response to energizing the RF circuit.

In some cases, the anatomical part can then be moved while the elastic and conductive loop 214 wraps the anatomical part, which stretches the elastic and conductive loop 214 to a new length. Then the MRI system 210 produces a new image. A series of images can be produced in this manner without unwrapping the elastic and conductive loop or other manual adjustment of the coil geometry 214. The elastic and conductive loop 214 can then be removed from the anatomical part of the patient so that the elastic and conductive loop 214 returns to its original length.

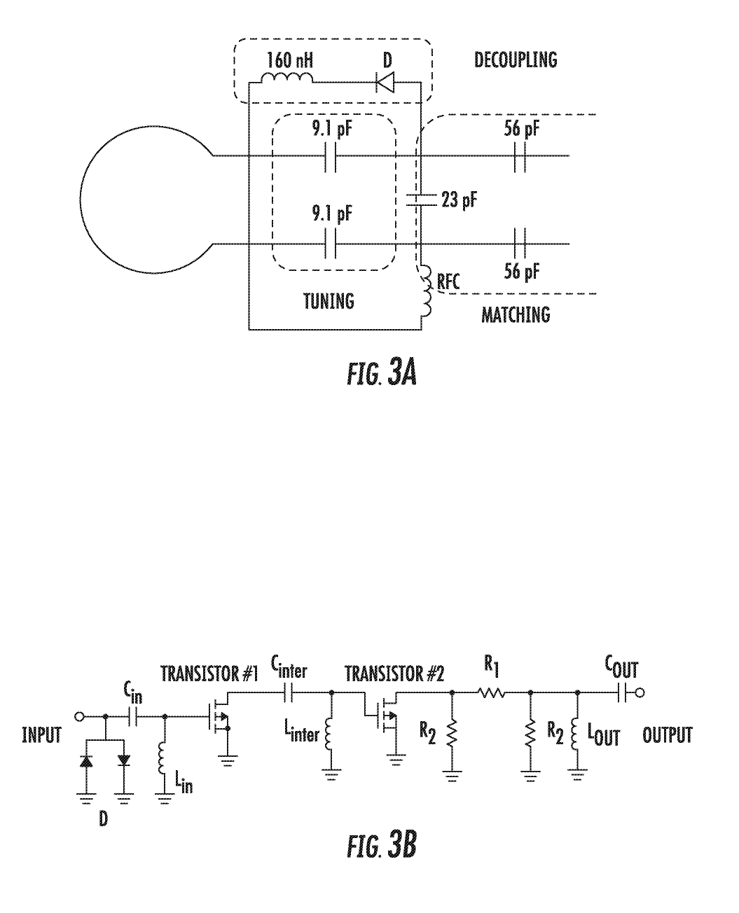

FIGS. 3A-B illustrate example RF circuits for an MRI system using an elastic RF coil. Existing RF techniques tune a coil by choosing capacitors of a specific value to cancel coil inductance, which is determined by the shape and length of a coil. The resulting resistive coil impedance is then transformed to 50- or 75-Ohm cable impedance via a matching circuit. Nearly all pre-amplifiers are designed to work optimally when its source (generator) impedance is equal to a designated cable impedance. If the source impedance changes, either the noise figure, the gain, or both of a pre-amplifier will deviate from their design. As a result, MRI image quality will degrade. For an array of RF coils, the decoupling between neighboring elements are minimized by overlapping them with an appropriate ratio. Otherwise, their strong noise correlation will degrade the quality of combined images. However, neither exact coil tuning nor overlapping is possible when elastic RF coils change their shape, length, and coverage area. The RF circuits described in this specification can mitigate these issues by using minimax tuning or a low-variability pre-amplifier or both.

Minimax Tuning.

Each RF coil is tuned with respect to the mean coil dimension in the expected range of variation. For instance, if a coil is expected to be stretched by 25% at most, the tuning is performed by stretching the coil by 12.5%. With respect to the mean coil size, the coil impedance will become either capacitive or inductive when the coil is relaxed or stretched. In either case, the maximum impedance deviation is minimized compared to tuning the coil with respect to other coil sizes.

FIG. 3A shows an example minimax tuning, impedance matching, and decoupling circuit that can be applied to the RF coils of FIGS. 2A-D. The circuit can include an LC-tank circuit for active coil decoupling during RF transmit. In general, any appropriate coil tuning method can be used to reduce the impedance variation. For instance, an alternative approach is automatic coil tuning, which typically measures the coil input impedance via an on-board RF reflectometer. The reflection is then transferred to a DC voltage to control the capacitance of a varactor diode. Although possible, the performance of automatic tuning could be sub-optimal because it is very difficult to acquire MRI signal while simultaneously measuring RF reflection at the same frequency.

Low-Variability Pre-Amplifier Design.

The impedance variation as the result of minimax coil tuning can be mitigated by a low-variability pre-amplifier design. More specifically, the following features can be implemented for such pre-amplifiers.

i. Low noise figure. Example pre-amplifiers have a noise figure within 1 dB, which corresponds to a 20% maximum SNR penalty.

ii. High gain. MRI pre-amplifiers are typically required to achieve 25-30 dB gain, or 300- to 1,000-fold increase of signal amplitude, for signal digitization.

iii. Unconditional stability. This is useful if the source impedance of a pre-amplifier changes.

iv. Low input impedance. This is desired in array design for the decoupling of neighboring elements. The basic idea is to adjust the cable length between the pre-amplifier input and the matching circuit output, so that the low pre-amplifier input impedance is transferred to a high impedance at coil terminal. This large impedance blocks the induced current and minimizes the coupling effect. For any pre-amplifiers intended to be applied in this way, the input impedance should be less than 1.5 or 2 Ohm.

v. Low noise-figure and gain variabilities. This is useful to maintain stable noise figure and gain performances when the pre-amplifier source impedance changes from its designated value as the result of stretching or shrining a RF coil.

In general, any appropriate pre-amplifier circuit can be used in the system to satisfy these criteria. FIG. 3B shows an example pre-amplifier circuit. The first stage is in charge of providing the required input impedance, noise figure, and performance variability. This is mainly accomplished by adjusting the quiescent point of the transistor and the input matching circuit consisting of Cᵢₙ and Lᵢₙ. The pair of diodes in front of the first-stage transistor is used for overload protection.

The second stage is mainly responsible for providing a sufficient gain. The gain can be controlled by either adjusting the attenuator that consists of R₁ and R₂, or the output matching circuit that consists of Cₒᵤₜ and Lₒᵤₜ, or both. The inter-stage impedance matching is accomplished by adjusting Cᵢₙₜₑᵣ and Lᵢₙₜₑᵣ, which can be optional in some designs. Other example RF pre-amplifiers can be designed that satisfy the above criteria. In general, the RF pre-amplifiers can be two-stage, have 30-dB gain, and be unconditionally stable with the same circuit schematic as shown in FIG. 3B. The pre-amplifiers can be designed with a 50- or 75-Ω or other source impedances. The input impedances of the pre-amplifiers can vary, e.g., between 0.1, 0.2, and 1Ω.

Some example pre-amplifiers were evaluated using the elastic coil shown in FIGS. 2A and 2B. This coil has a mean diameter of 9 cm. When it was positioned at 1.5-cm away from a head-shaped phantom, the load resistance is roughly 6Ω. An impedance matching circuit was designed to transform the coil impedance to 50-Ω cable impedance, which is also the designated pre-amplifier source impedance. When the coil is stretched to a 10-cm diameter circle or shrunk to an 8-cm diameter circle, which corresponds to a 25% size variation with respect to the mean coil diameter, both its inductance and load resistance change. The pre-amplifiers thus have a source impedance different from the designated 50-Ω. As the result, the noise figures and gains may change.

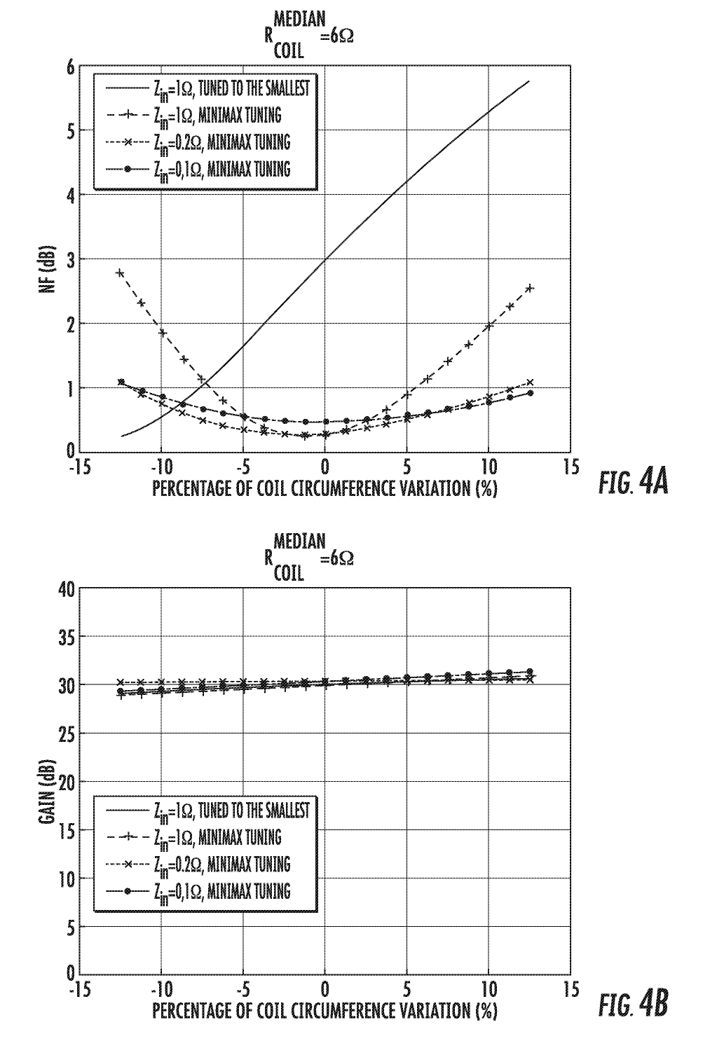

The performances of three example pre-amplifiers are compared in FIGS. 4A-B as a function of the percentile change of coil radius. FIG. 4A shows the noise figure and FIG. 4B shows the gain variations of different pre-amplifiers as a function of the percentile change of coil radius.

The gain variations of the three pre-amplifiers are not substantially different. The 0.2-Ω pre-amplifier appears to be the best, which is close to a straight line for different coil radii. The other two pre-amplifiers have a gain variation of ±1 dB. The 0.1-Ω pre-amplifier exhibits the smallest peak-to-peak variation and the lowest maximum noise figure in the entire range of coil size variation. The 0.2-Ω pre-amplifier has a lower noise figure for most coil sizes in general except for those being maximally stretched. The 1-Ω pre-amplifier has the lowest noise figure for a specific coil size, but the worst variation as the coil size changes.

Therefore, either the 0.1- or the 0.2-Ω pre-amplifier can be selected for elastic coils. If one prefers a generally lower noise figure, the 0.2-Ω pre-amplifier is a better choice. FIGS. 4A-B also show the performance of the 1-Ω pre-amplifier when the tuning was performed with respect to the smallest coil size. Its noise figure increases to nearly 6 dB when the coil is stretched to its maximum size. Consequently, the SNR is expected to reduce by four folds. These results demonstrate that both minimax tuning and low-variability pre-amplifier design are useful to maintain a good SNR for elastic coils.

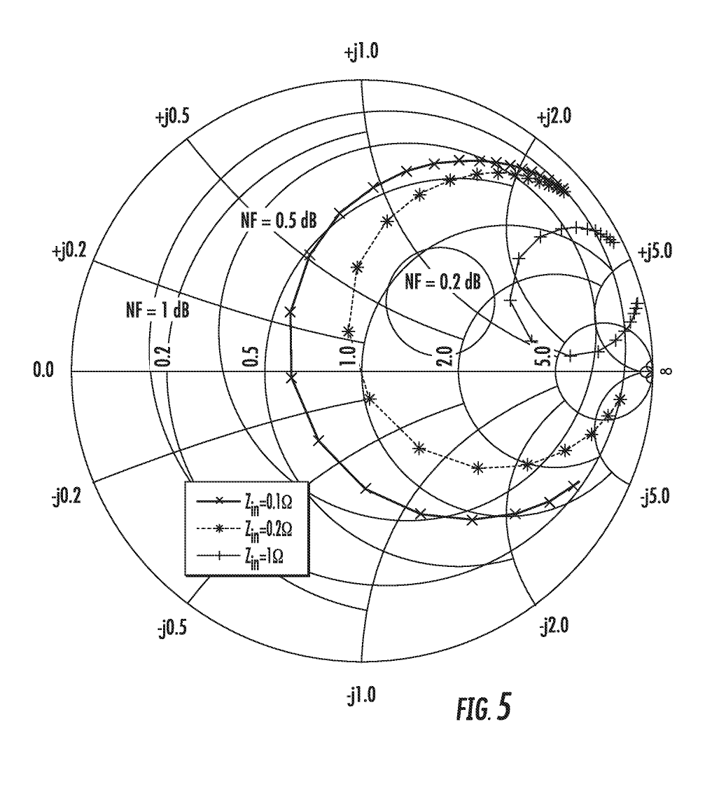

FIG. 5 is an example Smith chart that illustrates some design principles of low-variability pre-amplifiers. In general, for low-variability pre-amplifiers, it is useful to have the first-stage transistor source impedance located near the center of the Smith chart, i.e., 50Ω, when matched to the mean coil size.

The Smith chart plots the constant noise figure circles as a function of first-stage transistor source impedance. It also shows the transistor source impedance (after Cin and Lin) of the three pre-amplifiers as the result of varying the coil size. They all appear to be circles but centered differently and also with difference radii. In order to achieve low variability, the locus of the first-stage transistor source impedance should encircle, not being on one side of, the smallest constant noise figure circle. One strategy is to adjust the transistor source impedance that corresponds to the mean coil size as close as possible to the center of the Smith chart, i.e., 50Ω.

In practice, the ability of achieving this favorable feature may depend on the transistor being used and its bias condition. A practical pre-amplifier is often the result of trade-offs between competitive design requirements. For instance, a pre-amplifier configured for the lowest noise figure generally does not offer a low input impedance for mutual decoupling. Those configured for superior mutual decoupling often are not the best for low-variability appreciations. The MRI systems described in this specification can use any appropriate pre-amplifier configuration as long as the variabilities of noise figure and gain are within the satisfactory range.

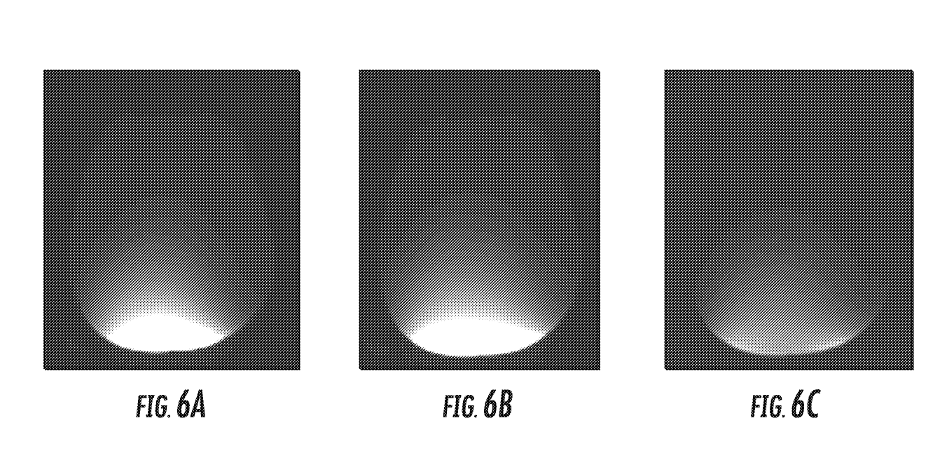

FIGS. 6A-C show 3-Tesla MRI images acquired by using the liquid-metal coil shown in FIGS. 2A-B. FIG. 6A shows the 3-Tesla phantom image acquired using the 8 cm coil with the 0.2-Ω pre-amplifier, FIG. 6B shows an image acquired using the 10-cm coil with the 0.2-Ω pre-amplifier, and FIG. 6C shows an image acquired using the 10-cm coil with the 1-Ω pre-amplifier.

The minimax tuning was performed by stretching the coil to have a 9-cm diameter and positioning it 1.5-cm away from the head-shaped phantom. Both of the images in FIGS. 6A and 6B were acquired by using the 0.2-Ω low-variability pre-amplifier. The coil was shrunk to have an 8-cm diameter and stretched to have a 10-cm diameter, respectively. High image qualities were observed in both cases. FIG. 6C shows the image of the 10-cm coil acquired by using the 1-Ω pre-amplifier and a tuning circuit designed for the 8-cm coil. Compared to the image of FIG. 6B, the SNR drops by nearly 3 folds. These results demonstrate the effectiveness of minimax tuning and the low-variability pre-amplifier.

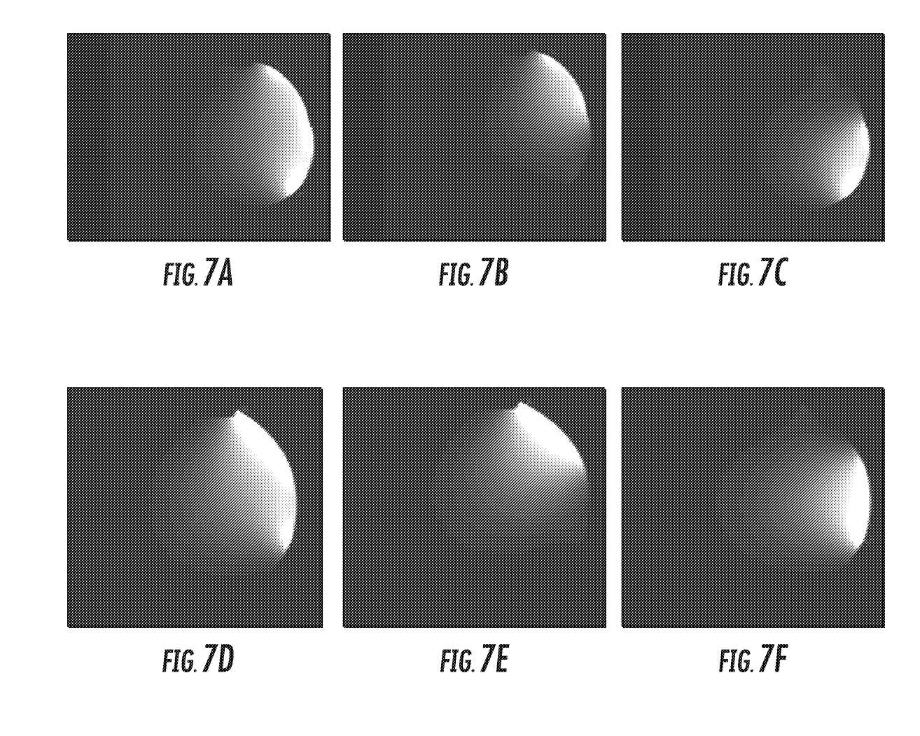

FIGS. 7A-F illustrate the ability of using the 0.2-Ω pre-amplifier for mutual decoupling. In FIGS. 7A-F, the two coils shown in FIGS. 2C and 2D were applied to acquire images of a head-shaped phantom and a spherical phantom, respectively. The two coils were positioned side-by-side without any overlapping for mutual decoupling. The decoupling was solely achieved by using the low input impedance of the pre-amplifiers. The distinctive coil sensitivities shown in the uncombined images demonstrate good decoupling results despite the shape and size variations of the coils and the phantoms.

FIGS. 7A and 7D show combined 3-Tesla images of a head-shaped phantom and a 15 cm spherical phantom. FIGS. 7B and 7C show uncombined 3-Tesla images of the head-shaped phantom. FIGS. 7E and 7F show uncombined 3-Tesla images of the spherical phantom. The uncombined images in FIGS. 7B-C and 7E-F show indiscernible coupling between the two coils.

Although specific examples and features have been described above, these examples and features are not intended to limit the scope of the present disclosure, even where only a single example is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed in this specification (either explicitly or implicitly), or any generalization of features disclosed, whether or not such features or generalizations mitigate any or all of the problems described in this specification. Accordingly, new claims may be formulated during prosecution of this application (or an application claiming priority to this application) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A system comprising:
a radio-frequency (RF) coil array comprising at least one elastic and conductive loop, the elastic and conductive loop having a length and being elastic in that, in response to a stress, the length stretches from a first length to a second length greater than the first length and returns to the first length after removal of the stress, wherein the at least one elastic and conductive loop is configurable to surround at least a portion of a magnetic resonance imaging subject's body for magnetic resonance imaging of the portion of the subject's body; and
an RF circuit coupled to the RF coil array and configured to cause a voltage to be induced through the elastic and conductive loop.

2. The system of claim 1, comprising a magnetic resonance imaging (MRI) system, wherein the RF circuit is coupled to the MRI system.

3. The system of claim 2, wherein the RF circuit comprises an impedance matching circuit configured for minimum impedance mismatching of the RF coil array to the MRI system when the length of the elastic and conductive loop deviates from a median length.

4. The system of claim 3, wherein the RF circuit comprises a low-variability pre-amplifier circuit, and wherein an electrical length between a pre-amplifier input and an output of the impedance matching circuit is configured so that an input impedance of the pre-amplifier is transformed into a large impedance, relative to an impedance of one or more coaxial cables coupled the RF circuit to the MRI system, at a specific location near a terminal of the RF circuit when going through the impedance matching circuit.

5. The system of claim 1, wherein the RF circuit comprises a frequency tuning circuit configured to resonate the RF coil array within a designed range of sizes and shapes of the elastic and conductive loop.

6. The system of claim 1, wherein the RF circuit comprises a decoupling circuit comprising one or more inductors forming a LC-tank or a large impedance transformed from a small resistance, or a capacitive or inductive impedance, via a transmission line of appropriate length.

7. The system of claim 1, wherein the elastic and conductive loop comprises an elastomer tube surrounding an amount of liquid metal.

8. The system of claim 1, wherein the elastic and conductive loop comprises an elastic sheath and stranded wire surrounded by the elastic sheath, the elastic sheath having an unstressed sheath length and a stranded wire having a stranded wire length greater than the unstressed sheath length.

9. The system of claim 1, comprising a deformable coil housing sized to fit an anatomical part, and wherein the RF coil array is mounted on or in the deformable coil housing.

10. The system of claim 9, wherein the deformable coil housing comprises at least one rigid part for mechanical support and one or more internal chambers inside the deformable coil each housing an individual coil, and one or more openings along the one or more internal chambers for threading conducting wires.

11. The system of claim 9, wherein the deformable coil housing comprises an elastic sleeve or cap member.

12. The system of claim 11, wherein the elastic sleeve or cap member comprises an elastic cap wearable on the subject's head to hold the at least one elastic and conductive loop in close proximity to the subject's head for magnetic resonance imaging of the subject's head.

13. The system of claim 11, wherein the elastic sleeve or cap member comprises an elastic sleeve wearable around one of the subject's joints to hold the at least one elastic and conductive loop in close proximity to the subject's joint for magnetic resonance imaging of the subject's joint.

14. A method for magnetic resonance imaging (MRI), the method comprising:
stretching a radio-frequency (RF) coil array to surround at least a portion of a magnetic resonance imaging subject's body, including stretching at least one elastic and conductive loop having a length, wherein stretching the elastic and conductive loop comprises stretching the length from a first length to a second length greater than the first length;
receiving an induced voltage through a RF circuit coupled to the elastic and conductive loop; and
producing at least one MRI image using a response to the induced voltage through the RF circuit and an MRI system coupled to the RF circuit.

15. The method of claim 11, wherein stretching the RF coil array comprises stretching the RF coil array to wrap a head, knee, or shoulder.

16. The method of claim 11, comprising:
after producing the at least one MRI image, moving the anatomical part while the RF coil array wraps the anatomical part, thereby stretching the elastic and conductive loop to a new length; and
producing at least one additional MRI image after moving the anatomical part and stretching the elastic and conductive loop to the new length.

17. The method of claim 11, comprising releasing the elastic and conductive loop so that the length of the elastic and conductive loop returns to the first length.

18. The method of claim 11, wherein the RF circuit comprises an impedance matching circuit configured for impedance matching the RF coil array to the MRI system regardless of whether the length of the elastic and conductive loop is stretched to the second length or not.

19. The method of claim 15, wherein the RF circuit comprises a pre-amplifier circuit, and wherein an electrical length between a pre-amplifier input and an output of the impedance matching circuit is configured so that an input impedance of the pre-amplifier is transformed into a large impedance, relative to an impedance of one or more coaxial cables coupled the RF circuit to the MRI system, at a specific location near a terminal of the RF circuit when going through the impedance matching circuit.

20. The method of claim 11, wherein the RF circuit comprises a frequency tuning circuit configured to resonate the RF coil array within a designed range of sizes and shapes of the elastic and conductive loop.

21. The method of claim 11, wherein the RF circuit comprises a decoupling circuit comprising one or more inductors and one or more inductors forming a LC-tank or a large impedance obtained via an impedance transfer circuit.

22. The method of claim 11, wherein the elastic and conductive loop comprises an elastomer tube surrounding an amount of liquid metal.

23. The method of claim 11, wherein the elastic and conductive loop comprises an elastic sheath and stranded wire surrounded by the elastic sheath, the elastic sheath having an unstressed sheath length and a stranded wire having a stranded wire length greater than the unstressed sheath length.
